(19) United States
(12) Patent Application Publication
(10) Pub. No.: US 2023/0238293 A1
(43) Pub. Date: Jul. 27, 2023

(54) SEMICONDUCTOR DEVICE LAYOUT STRUCTURE AND METHOD FOR MANUFACTURING SEMICONDUCTOR DEVICE LAYOUT STRUCTURE

(71) Applicant: CHANGXIN MEMORY TECHNOLOGIES, INC., Hefei City (CN)

(72) Inventor: Yumeng SUN, Hefei City (CN)

(73) Assignee: CHANGXIN MEMORY TECHNOLOGIES, INC., Hefei City (CN)

(21) Appl. No.: 17/804,354

(22) Filed: May 27, 2022

Related U.S. Application Data
(63) Continuation of application No. PCT/CN2022/079052, filed on Mar. 3, 2022.

(30) Foreign Application Priority Data
Jan. 27, 2022 (CN) 202210102070.2

(51) Int. Cl. H01L 21/66; H01L 29/06

(52) U.S. Cl. CPC H01L 22/32; H01L 29/0692

(57) ABSTRACT

A semiconductor device layout structure includes: an active area layout layer including a plurality of first active area patterns, and at least one second active area pattern each connected to at least two of the plurality of first active area patterns; a drain contact layer configured to form a plurality of drain contact plugs and arranged on each first active area pattern; a source contact layer configured to form a source contact plug and arranged on the at least one second active area pattern; and a gate layer including a plurality of gate patterns extending in a first direction, the plurality of gate patterns being arranged over the plurality of first active area patterns at a position away from the drain contact layer and configured to form a plurality of gates.

### CROSS-REFERENCE TO RELATED APPLICATIONS

This is a continuation application of International Patent Application No. PCT/CN2022/079052 filed on Mar. 3, 2022, which claims priority to Chinese Patent Application No. 202210102070.2 filed on Jan. 27, 2022. The disclosures of these applications are hereby incorporated by reference in their entirety.

### BACKGROUND

With the continuous reduction of the characteristic dimension of the semiconductor device, integrated circuits have developed from integrating dozens of devices on a single chip to integrating millions of devices on a single chip. The density of traditional integrated circuits cannot meet the current needs any longer. Therefore, the density of the integrated circuits needs to be increased continuously. The complexity and the performance of the integrated circuits can be improved by increasing the density of the integrated circuits, so that the manufacture of the semiconductor devices is more challenging.

### SUMMARY

The disclosure relates, but is not limited, to a semiconductor device layout structure and a method for manufacturing a semiconductor device layout structure.

In view of this, embodiments of the disclosure provide a semiconductor device layout structure and a method for manufacturing a semiconductor device layout structure.

In a first aspect, an embodiment of the disclosure provides a semiconductor device layout structure. The semiconductor device layout structure includes: an active area layout layer, in which the active area layout layer includes a plurality of first active area patterns, and at least one second active area pattern each connected to at least two of the plurality of first active area patterns;
a drain contact layer, in which the drain contact layer is configured to form a plurality of drain contact plugs and is arranged on each first active area pattern;
a source contact layer, in which the source contact layer is configured to form a source contact plug and is arranged on the at least one second active area pattern;
a gate layer, in which the gate layer includes a plurality of gate patterns extending in a first direction, and the plurality of gate patterns are arranged over the plurality of first active area patterns at a position away from the drain contact layer and are configured to form a plurality of gates.

The gate layer, the active area layout layer, the source contact layer, and the drain contact layer are configured to form at least two semiconductor sub-devices, and the at least two semiconductor sub-devices share one source contact plug.

In a second aspect, an embodiment of the disclosure provides a method for manufacturing a semiconductor device layout structure, which includes the following operations.

A semiconductor substrate is provided.

An active area layout layer is formed on the semiconductor substrate, in which the active area layout layer includes a plurality of first active area patterns and a plurality of second active area patterns, and each second active area pattern is connected to at least two of the plurality of first active area patterns.

A drain contact layer is formed on each first active area pattern, in which the drain contact layer is configured to form a plurality of drain contact plugs.

A source contact layer is formed on each second active area pattern, in which the source contact layer is configured to form a source contact plug.

A gate layer is formed over the plurality of first active area patterns at a position away from the drain contact layer.

The gate layer, the active area layout layer, the source contact layer, and the drain contact layer are configured to form at least two semiconductor sub-devices, and the at least two semiconductor sub-devices share one source contact plug.

### BRIEF DESCRIPTION OF THE DRAWINGS

One or more embodiments are exemplarily explained through the figures in the accompanying drawings corresponding thereto, these exemplary explanations do not constitute a limitation to the embodiments, elements having the same reference numerals in the accompanying drawings are denoted as similar elements; and unless otherwise specifically declared, the figures in the accompanying drawings do not constitute a limitation of proportion.

FIG. 1 is a schematic diagram of a semiconductor device layout structure according to an embodiment of the disclosure;

FIG. 2A is a first schematic diagram of a semiconductor device layout structure according to an embodiment of the disclosure;

FIG. 2B is a second schematic diagram of a semiconductor device layout structure according to an embodiment of the disclosure;

FIG. 2C is a third schematic diagram of a semiconductor device layout structure according to an embodiment of the disclosure;

FIG. 2D is a fourth schematic diagram of a semiconductor device layout structure according to an embodiment of the disclosure;

FIG. 2E is a fifth schematic diagram of a semiconductor device layout structure according to an embodiment of the disclosure;

FIG. 3 is a schematic diagram of a semiconductor device layout structure before being improved according to an embodiment of the disclosure;

FIG. 4 is a schematic diagram of a semiconductor device layout structure after being improved according to an embodiment of the disclosure;

FIG. 5 is a flowchart of a method for manufacturing a semiconductor device layout structure according to an embodiment of the disclosure;

FIG. 6 is a first schematic diagram of an active area layout layer according to an embodiment of the disclosure;

FIG. 7 is a second schematic diagram of an active area layout layer according to an embodiment of the disclosure;

FIG. 8 is a schematic diagram showing formation of a drain contact layer according to an embodiment of the disclosure;

FIG. 9 is a schematic diagram showing formation of a source contact layer according to an embodiment of the disclosure;

FIG. 10 is a schematic diagram showing formation of a gate layer according to an embodiment of the disclosure;

FIG. 11 is a schematic diagram showing formation of an overlapping area pattern according to an embodiment of the disclosure; and

FIG. 12 is a schematic diagram showing formation of an overlapping area pattern according to an embodiment of the disclosure.

### DESCRIPTION OF REFERENCE NUMERALS

10-semiconductor device layout structure; 101-active area layout layer; 102-gate layer; 103-source contact layer; 104-drain contact layer; 20-semiconductor device layout structure; 201-active area layout layer; 2011-first active area pattern; 2012-second active area pattern; 202-drain contact layer; 203-source contact layer; 204-gate layer; 205-semiconductor sub-device; 206-protruding pattern; 207-overlapping area pattern; 208-first protruding pattern; 209-second protruding pattern; 30-layout structure before being improved; 301-active area layout layer; 302-gate layer; 303-drain contact layer; 304-source contact layer; 40-layout structure after being improved; 401-active area layout layer; 4011-first active area pattern; 4012-second active area pattern; 4013-protruding pattern; 402-gate layer; 403-drain contact layer; 404-source contact layer; 60-active area layout layer; 601-first active area pattern; 602-second active area pattern; 602-1-projection region of second active area pattern; 70-active area layout layer; 701-first layer of mask pattern; 702-second layer of mask pattern; 801-first active area pattern; 802-second active area pattern; 803-drain contact layer; 901-source contact layer; 110-gate layer; 111-overlapping area pattern; 121-first protruding pattern; 122-second protruding pattern.

### DETAILED DESCRIPTION

Exemplary embodiments of the disclosure will be described in more detail below with reference to the accompanying drawings. Although the exemplary embodiments of the disclosure are shown in the accompanying drawings, it should be understood that the disclosure can be implemented in various forms and cannot be limited by the embodiments illustrated herein. On the contrary, these embodiments are provided to more thoroughly understand the disclosure and to completely convey the scope of the disclosure to those skilled in the art.

In the following description, numerous specific details are set forth in order to provide a more thorough understanding of the disclosure. However, it will be apparent to those skilled in the art that the disclosure can be implemented without one or more of these details. In other examples, in order to avoid confusion with the disclosure, some technical features known in the art are not described. That is, all the features of the actual embodiments are not described here, and the well-known functions and structures are not described in detail.

In the accompanying drawings, the sizes and relative size of layers, regions, and elements may be exaggerated for clarity. The same reference numerals denote the same elements from beginning to end.

It should be understood that, when an element or layer is described as being “on”, “adjacent to”, “connected to” or “coupled to” another element or layer, it can be directly on, adjacent to, connected to, or coupled to the other element or layer, or there can be an intermediate element or layer. In contrast, when an element is described as being “directly on”, “directly adjacent to”, “directly connected to” or “directly coupled to” another element or layer, there are no intermediate element or layer. It should be understood that although the terms “first”, “second”, “third” and so on may be used to describe various elements, components, regions, layers, and/or portions, these elements, components, regions, layers, and/or portions should not be limited by these terms. These terms are used merely to distinguish an element, component, region, layer, or portion from another element, component, region, layer, or portion. Therefore, a first element, component, region, layer, or portion discussed below may be described as a second element, component, region, layer, or portion without departing from the teachings of the present disclosure. When the second element, component, region, layer or portion is discussed, it does not mean that the first element, component, region, layer or portion is necessarily present in the present disclosure.

Terms used herein are for the purpose of describing specific embodiments only and are not intended to be limiting of the disclosure. As used herein, “a/an”, “one”, and “the” in singular forms are also intended to include a plural form unless the context clearly indicates other forms. It should also be understood that the terms “consist” and/or “include” when used in the specification, determine the presence of the features, integers, steps, operations, elements, and/or components, but do not exclude the presence or addition of one or more other features, integers, steps, operations, elements, components, and/or groups. As used herein, the term “and/or” includes any and all combinations of the related listed items.

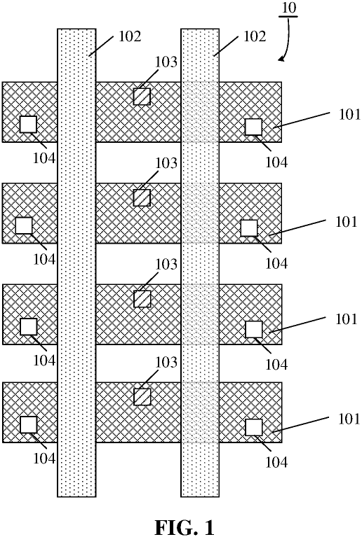

FIG. 1 is a schematic diagram of a semiconductor device layout structure according to an embodiment of the disclosure. As shown in FIG. 1, the semiconductor device layout structure 10 provided by an embodiment of the disclosure includes a plurality of sub-device layouts. Each sub-device layout includes an active area layout layer 101, a gate layer 102, a source contact layer 103, and a drain contact layer 104. In the embodiment of the disclosure, since the plurality of active area layout layers 101 are independent of each other, the drive capability of the field effect transistor formed in the semiconductor device layout structure in the embodiment of the disclosure is relatively weak, and there is a problem of winding during connection with the back-end metal.

On the basis of the problems in the above embodiment, the embodiments of the disclosure further provide a semiconductor device layout structure and a method for manufacturing a semiconductor device layout structure. The semiconductor device layout structure includes an active area layout layer, a gate layer, a drain contact layer, and a source contact layer. The active area layout layer includes first active area patterns and second active area patterns, and each second active area pattern is connected to at least two first active area patterns. The active area pattern layer, the gate layer extending in the first direction, the drain contact layer arranged on the first active area patterns, and the source contact layer arranged on the second active area patterns are configured to form at least two semiconductor sub-devices. In the embodiments of the disclosure, the active areas of the semiconductor sub-devices are connected to each other. As such, it can not only improve the drive capability of the field effect transistor in the semiconductor device layout structure, but also reduce the problem of winding during connection with the back-end metal.

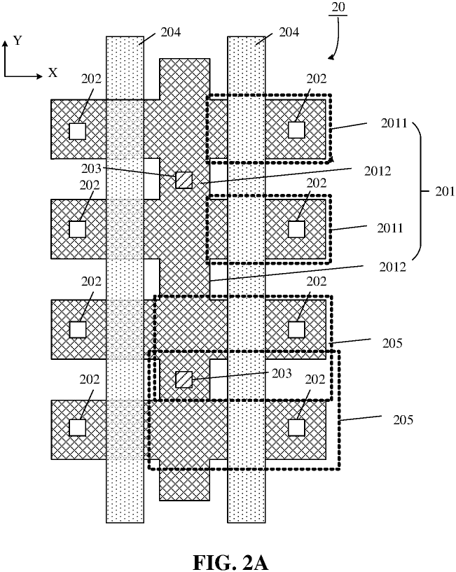

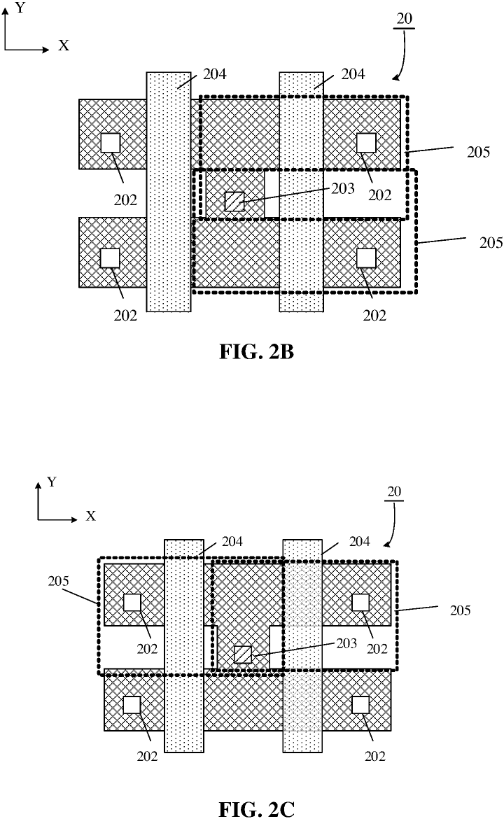

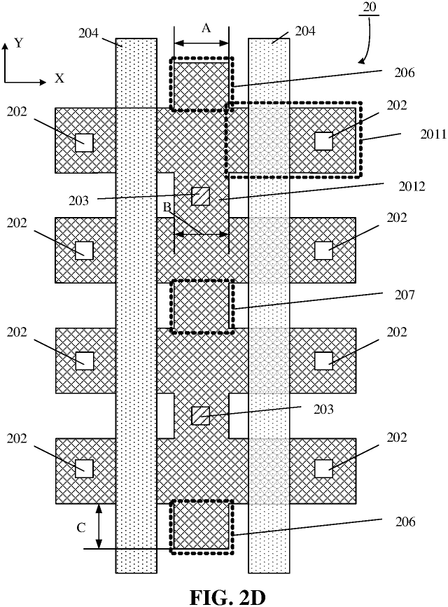

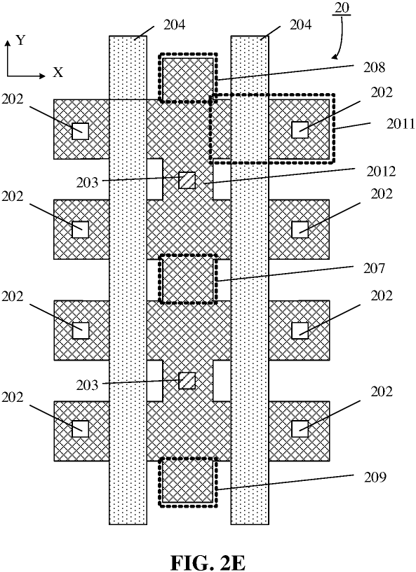

FIG. 2A to FIG. 2E are schematic diagrams of a semiconductor device layout structure according to an embodiment of the disclosure. As shown in FIG. 2A to FIG. 2C, the semiconductor device layout structure 20 includes an active area layout layer 201, a drain contact layer 202, a source contact layer 203, and a gate layer 204. The active area layout layer 201 includes a plurality of first active area patterns 2011 and a plurality of second active area patterns 2012. Each second active area pattern is connected to at least two first active area patterns 2011. The gate layer 204 includes a plurality of gate patterns extending in a first direction. The drain contact layer 202 is configured to form a plurality of drain contact plugs and is arranged on each first active area pattern 2011. The source contact layer 203 is configured to form a source contact plug and is arranged on each second active area pattern 2012.

The active area layout layer 201, the gate layer 204, the drain contact layer 202, and the source contact layer 203 are configured to form at least two semiconductor sub-devices 205. The at least two semiconductor sub-devices 205 share one source contact plug.

Referring to FIG. 2B, FIG. 2B is a schematic diagram of a semiconductor device layout structure according to an embodiment of the disclosure. In the embodiment of the disclosure, as shown in FIG. 2B, the at least two semiconductor sub-devices 205 formed by the semiconductor device layout structure 20 are arranged parallel to each other in the first direction (the Y-axis direction as shown in FIG. 2B), and the at least two semiconductor sub-devices 205 share one gate 204.

Referring to FIG. 2C, FIG. 2C is a schematic diagram of a semiconductor device layout structure according to an embodiment of the disclosure. In the embodiment of the disclosure, as shown in FIG. 2C, the at least two semiconductor sub-devices 205 formed by the semiconductor device layout structure 20 are arranged parallel to each other in the second direction (the X-axis direction as shown in FIG. 2C). Each semiconductor sub-device 205 corresponds to a respective one of the gates 204 arranged parallel to each other in the second direction (the X-axis direction).

In the embodiments of the disclosure, the first direction (the Y-axis direction) is perpendicular to the second direction (the X-axis direction).

Referring to FIG. 2B and FIG. 2C, in the embodiment of the disclosure, at least two semiconductor sub-devices 205 formed by the layout structure 20 are arranged parallel to each other in the first direction (the Y-axis direction), at least two semiconductor sub-devices 205 are arranged parallel to each other in the second direction (the X-axis direction), and at least four semiconductor sub-devices 205 share one source contact plug on one source contact layer 203.

Referring to FIG. 2D, FIG. 2D is a schematic diagram of a semiconductor device layout structure according to an embodiment of the disclosure. In the embodiment of the disclosure, as shown in FIG. 2D, the active area layout layer 201 further includes at least one protruding pattern 206. The width A of the protruding pattern 206 is equal to the width B of each second active area pattern 2012, and the length C of the protruding pattern is less than or equal to the width A. In the embodiment of the disclosure, the width refers to a layout length of each second active area pattern 2012 in the second direction (the X-axis direction), and the length refers to the layout length of each second active area pattern 2012 in the first direction (the Y-axis direction).

Referring to FIG. 2D, in the embodiment of the disclosure, the active area layout layer 201 further includes at least one overlapping area pattern 207. At least four semiconductor sub-devices 205 formed by the layout structure 20 are arranged parallel to each other in the first direction. The layout structure 20 includes at least two second active area patterns 2012. The at least two second active area patterns 2012 are connected to each other through the at least one overlapping area pattern 207.

Referring to FIG. 2E, in the embodiment of the disclosure, the active area layout layer 201 further includes at least two protruding patterns, such as a first protruding pattern 208 and a second protruding pattern 209. The first protruding pattern 208 is connected to an end of one second active area pattern 2012, and the second protruding pattern 209 is connected to an end of the other second active area pattern 2012 away from the first protruding pattern 208.

Referring to FIG. 2E, in the embodiment of the disclosure, the semiconductor device layout structure 20 at least includes two gate layers 204. The two gate layers 204 are respectively arranged on both sides of the second active area pattern 2012, and the two gate layers 204 are arranged parallel to each other in the second direction (the X-axis direction). In the embodiment of the disclosure, in the first direction (the Y-axis direction), two adjacent semiconductor sub-devices 205 share one gate layer 204.

In some embodiments, the semiconductor device layout structure 20 may further include a wire layer (not shown in the figures). The source contact layer, the drain contact layer and the gate layer are respectively connected to a source test node, a drain test node, and a gate test node through the wire layer. As shown in FIG. 2A to FIG. 2E, the source contact layer and the drain contact layer are alternatively arranged, so that it can prevent the correspondingly connected wire layers from winding and overlapping with each other, thereby improving the flexibility of the layout.

In the semiconductor device layout structure provided by the embodiments of the disclosure, since the active area layout layer includes two additional protruding areas, the protruding areas apply stress downward. When the stress is applied to a channel area at the lower portion of the gate, it is beneficial to improving the drive capability of the field effect transistor in the layout structure. For an N-type field effect transistor, tensile stress can improve the drive capability of electrons. For a P-type field effect transistor, compressive stress can improve the drive capability of holes.

In the semiconductor device layout structure provided by the embodiments of the disclosure, the semiconductor sub-devices share the same second active area pattern, that is, the semiconductor sub-devices share one source contact plug. Compared with the active area layout layers independent of each other, the area of the source active area is increased, and more charges can be stored in the source area, so that the drive capability of the field effect transistor in the semiconductor device layout structure can be improved. Moreover, the positions of the source contact plugs and the drain contact plugs are alternatively arranged, so that it can facilitate connection of the back-end wire to the winding of the respective test node, thereby enlarging the layout space.

The semiconductor device layout structure provided by the embodiments of the disclosure can be applied to a peripheral circuit of any semiconductor device, such as a flash memory, a static random access memory, a dynamic random access memory, a phase change memory, a resistive memory, and a ferroelectric memory.

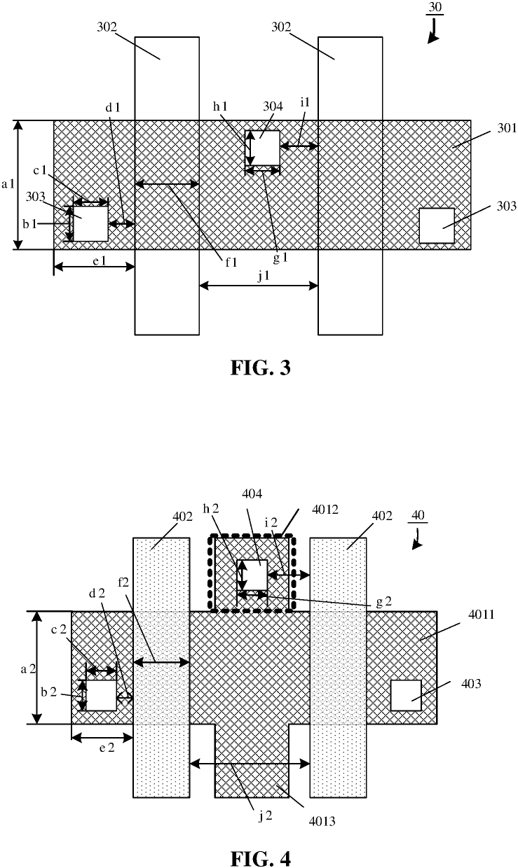

FIG. 3 and FIG. 4 are schematic diagrams respectively showing a semiconductor device layout structure before and after being improved according to an embodiment of the disclosure. FIG. 3 shows a layout structure before being improved. FIG. 4 shows a layout structure after being improved. The advantages of the semiconductor device layout structures before and after being improved are respectively described with reference to FIG. 3 and FIG. 4.

As shown in FIG. 3 and FIG. 4, the layout structure 30 before being improved includes an active area layout layer 301, as well as two gate layers 302, two drain contact layers 303 and a common source contact layer 304 arranged on the active area layout layer 301. The layout structure 40 after being improved includes an active area layout layer 401 (the active area layout layer 401 includes a first active area pattern 4011, a second active area pattern 4012, and a protruding pattern 4013), two gate layers 402 and two drain contact layers 403 arranged on the first active area pattern 4011, and a common source contact layer 404 arranged on the second active area pattern 4012. The width a1 of the active area layout layer 301 is equal to the width a2 of the first active area pattern 4011. The length f1 of the gate layer 302 is equal to the length f2 of the gate layer 402. The area b1*c1 of the drain contact layer 303 is equal to the area b2*c2 of the drain contact layer 403. The area g1*h1 of the source contact layer 304 is equal to the area g2*h2 of the source contact layer 404. The distance d1 between the drain contact layer 303 and the gate layer 302 is equal to the distance d2 between the drain contact layer 403 and the gate layer 402. The distance il between the source contact layer 304 and the gate layer 302 is equal to the distance i2 between the source contact layer 404 and the gate layer 402. The distance j1 between the two gate layers 302 is equal to the distance j2 between the two gate layers 402. The difference between the layout layer before being improved and the layout layer after being improved is that the active area layout layer 401 of the layout structure 40 after being improved includes the second active area pattern 4012, which is provided with the source contact layer 404. Thus, the active area layout layer 401 of the layout structure after being improved has a larger area. The active area layout layer 401 further includes a protruding pattern 4013.

In some embodiments, the second active area pattern increases the area of the source, increases the charge storage amount, and increases the drive current. The protruding pattern produces additional stress effects on electrons or holes through tensile stress or compressive stress, so as to improve the drive capability.

In the embodiment of the disclosure, performance tests are performed on the field effect transistors formed by the layout structures before and after being improved. The test results are shown in Table 1.

TABLE1

Test results of field effect transistors

| Type | Threshold voltage/V | Saturation current/µA | Pinch-off current/pA |
|---|---|---|---|
| Before being improved | 0.266 | 73 | 16266 |
| After being improved | 0.254 | 76 | 21859 |

It can be seen from the above test results that, in a case where other dimensions are completely the same, the increase in the area of the active area will increase the amount of ions implanted into the source area, that is, the number of carriers in the source area will increase, so that the saturation current of the field effect transistor can be increased, and the drive capability of the field effect transistor can be improved, thereby improving the control capability of the integrated circuits. It can effectively increase the saturation current for some field effect transistors that are not sensitive to the change in the length of the gate or the width of the gate.

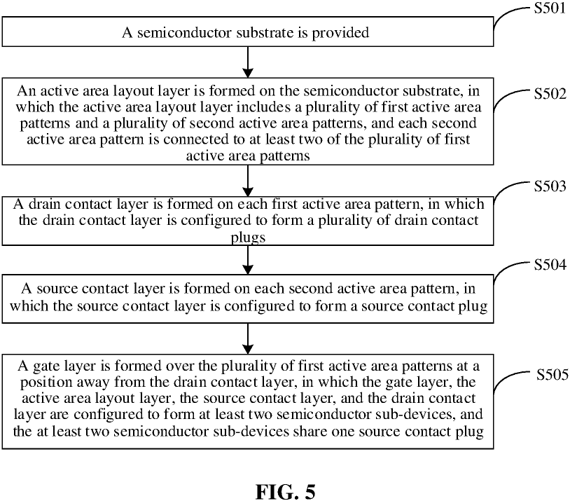

Besides, the embodiment of the disclosure further provides a method for manufacturing a semiconductor device layout structure. FIG. 5 is a flowchart of a method for manufacturing a semiconductor device layout structure according to an embodiment of the disclosure. As shown in FIG. 5, the method for manufacturing the semiconductor device layout structure includes the following operations.

In S501, a semiconductor substrate is provided.

In S502, an active area layout layer is formed on the semiconductor substrate. The active area layout layer includes a plurality of first active area patterns and a plurality of second active area patterns, and each second active area pattern is connected to at least two of the plurality of first active area patterns.

In S503, a drain contact layer is formed on each first active area pattern. The drain contact layer is configured to form a plurality of drain contact plugs.

In S504, a source contact layer is formed on each second active area pattern. The source contact layer is configured to form a source contact plug.

In S505, a gate layer is formed over the plurality of first active area patterns at a position away from the drain contact layer. The gate layer, the active area layout layer, the source contact layer, and the drain contact layer are configured to form at least two semiconductor sub-devices. The at least two semiconductor sub-devices share one source contact plug.

In the embodiments of the disclosure, the semiconductor substrate may be a silicon substrate. The semiconductor substrate may also include other semiconductor elements such as germanium (Ge), or may include semiconductor compounds such as silicon carbide (SiC), gallium arsenide (GaAs), gallium phosphide (GaP), indium phosphide (InP), indium arsenide (InAs), or indium antimonide (InSb), or may include other semiconductor alloys such as silicon germanium (SiGe), gallium arsenide phosphide (GaAsP), indium aluminum arsenide (AlInAs), gallium aluminum arsenide (AlGaAs), indium gallium arsenide (GaInAs), indium gallium phosphide (GaInP), and/or indium gallium arsenide phosphide (GaInAsP) or a combination thereof.

In the embodiment of the disclosure, multiple active areas are isolated from each other through shallow trenches.

In the embodiment of the disclosure, a first direction and a second direction that intersect with each other (for example, perpendicular to each other) are defined in the directions of a top surface and a bottom surface of a semiconductor substrate (i.e., a plane where the semiconductor substrate is located).

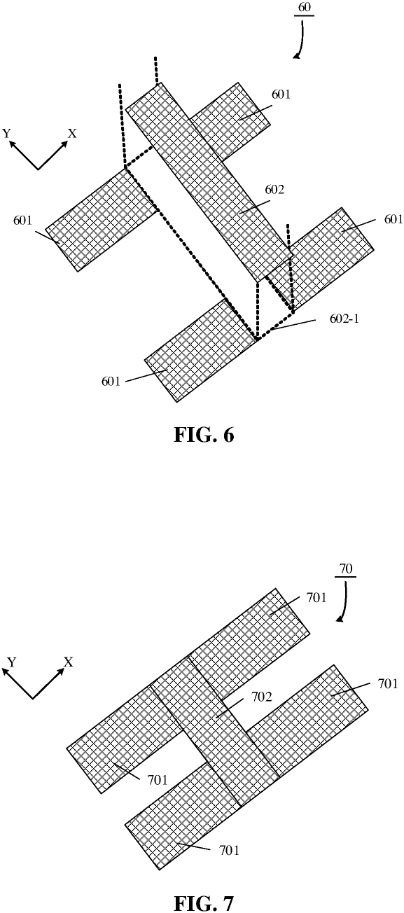

FIG. 6 and FIG. 7 are schematic diagrams of an active area layout layer according to an embodiment of the disclosure. S502 is executed with reference to FIG. 6 and FIG. 7, which describe a process of forming an active area layout layer. In some embodiments, referring to FIG. 6, the active area layout layer 60 may be formed through the following operations.

Operation 1: a plurality of first active area patterns 601 arranged in an array in the first direction (the Y-axis direction) and the second direction (the X-axis direction) are formed on the semiconductor substrate, in which the first active area patterns 601 extend in the second direction (the X-axis direction), and the second direction (corresponding to the Y-axis direction in FIG. 6) is perpendicular to the first direction.

Operation 2: a plurality of second active area patterns 602, which extend in the first direction and are spaced apart from each other, are formed in the first direction (the Y-axis direction), in which four first active area patterns 601 of the plurality of first active area patterns are connected to a respective one second active area pattern 602. A projection region 602-1 of the second active area pattern is shown in the figure.

Operation 3: the active area layout layer 60 is formed through the plurality of first active area patterns 601 and the plurality of second active area patterns 602.

In some embodiments, referring to FIG. 7, the active area layout layer 70 may also be formed by the following operations.

Operation 1: an H-shaped first layer of mask pattern is formed, in which the first layer of mask pattern includes first active area patterns 701 arranged in an array in the first direction (the Y-axis direction) and the second direction (the X-axis direction), and second active area patterns 702 extend in the first direction.

Then, S503 is executed, in which a drain contact layer is formed on each first active area pattern.

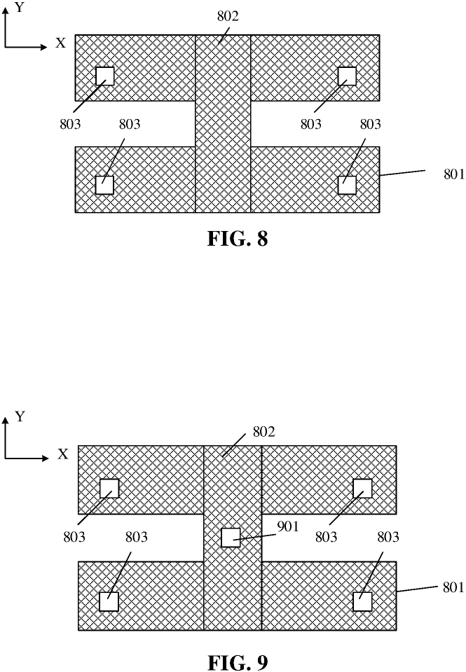

In some embodiments, FIG. 8 is a schematic diagram showing formation of a drain contact layer according to an embodiment of the disclosure. As shown in FIG. 8, in S503, a drain contact layer 803 can be formed at one end of the first active area pattern 801 away from the second active area pattern 802. The drain contact layer 803 is configured to form a plurality of drain contact plugs.

In some embodiments, the drain contact layer 803 may be formed by performing ion implantation on a portion of the first active area patterns 801, so as to reduce the contact resistance of the formed drain contact plugs, and improve the drive capability of the field effect transistor.

Then, S504 is executed, in which a source contact layer is formed on the second active area pattern.

In the embodiment of the disclosure, based on FIG. 8, FIG. 9 is a schematic diagram showing formation of a source contact layer according to an embodiment of the disclosure. As shown in FIG. 9, a source contact layer 901 is formed at a central position of each second active area pattern 802, and the source contact layer 901 is configured to form a source contact plug. It is to be noted that the embodiment of the disclosure only schematically shows that the source contact layer 901 is formed at the central position of one second active area pattern 802. There are multiple second active area patterns 802 in the embodiments of the disclosure.

In some embodiments, the source contact layer 901 may be formed by performing ion implantation on a portion of the second active area patterns 802, so as to reduce the contact resistance of the formed source contact plug, and improve the drive capability of the field effect transistor.

In some embodiments, the drain contact plug and the source contact plug are configured to connect to the source test node and the drain test node through wires, so as to test the source contact layer and the drain contact layer.

In some embodiments, the materials of the drain contact layer 803 and the source contact layer 901 may include at least one of titanium nitride (TiN), tantalum nitride (TaN), hafnium nitride (HfN), aluminum tantalum nitride (TaAlN), or aluminum titanium nitride (TiAlN), etc.

Then, S505 is executed, in which the gate layer is formed over the first active area patterns at a position away from the drain contact layer.

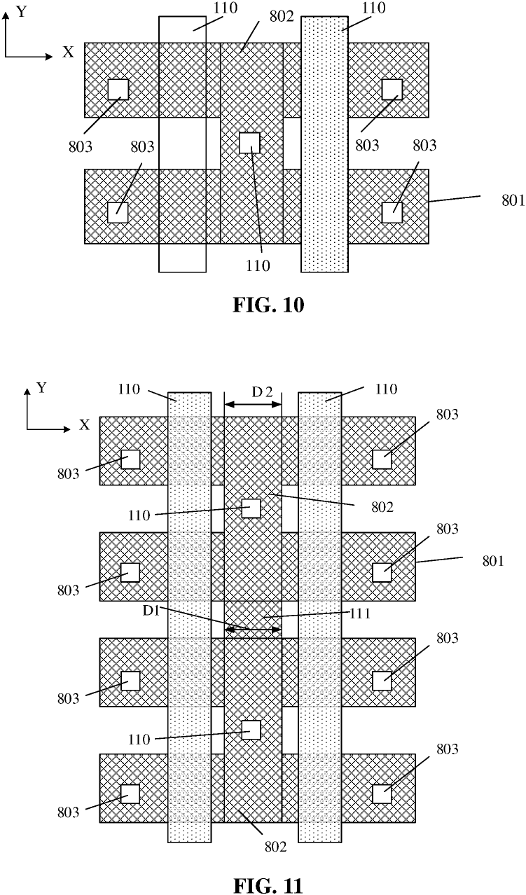

In the embodiment of the disclosure, based on FIG. 8, FIG. 10 is a schematic diagram showing formation of a gate layer according to an embodiment of the disclosure. As shown in FIG. 10, the gate layer 110 including gate patterns extending in the first direction may be formed over the first active area patterns 801, in which the gate layer 110 is arranged at the position away from the drain contact layer 803.

In some embodiments, each active area layout layer is provided with at least two gate layers 110. Each gate layer 110 extends in the first direction, and two gate layers 110 are arranged parallel to each other in the second direction.

It is to be noted that the source contact layer and the drain contact layer may be formed in any sequence. In the embodiment of the disclosure, the forming sequence of the source contact layer and the drain contact layer is not limited.

In some embodiments, the method for manufacturing the semiconductor device layout structure further includes the following operation. A wire layer is formed, in which one end of the wire layer is respectively connected to the source contact layer 803, the drain contact layer 901 and the gate layer 110, and the other end of the wire layer is respectively connected to a source test node, a drain test node and a gate test node. The source test node, the drain test node and the gate test node respectively test the source contact layer 803, the drain contact layer 901 and the gate layer 110 through the wire layer. For example, the working voltage may be applied to the gate through the gate test node, so that the test current corresponding to the source and the drain may be obtained from the source test node and the drain test node.

In some embodiments, based on FIG. 8, FIG. 11 is a schematic diagram showing formation of an overlapping area pattern according to an embodiment of the disclosure. As shown in FIG. 11, the method for manufacturing the semiconductor device layout structure further includes the following operation. An overlapping area pattern 111, which is connected to two adjacent second active area patterns 802, is formed between the two adjacent second active area patterns 802 in the first direction, in which the width D1 of the overlapping area pattern 111 is equal to the width D2 of the second active area pattern 802, and the width refers the layout length of the second active area pattern in the second direction.

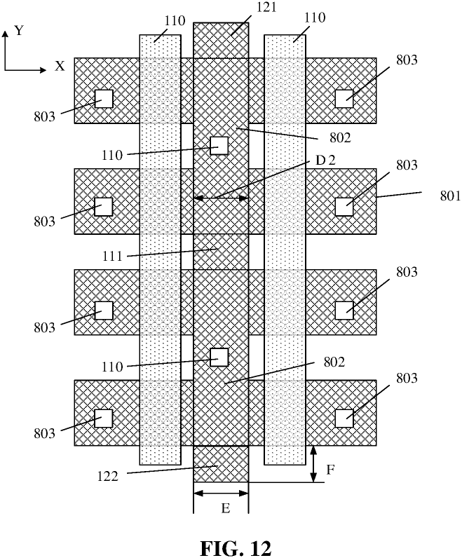

In some embodiments, based on FIG. 8, FIG. 12 is a schematic diagram showing formation of an overlapping area pattern according to an embodiment of the disclosure. As shown in FIG. 12, the second active area patterns 802 and the overlapping area pattern 111 form a connection pattern after the overlapping area pattern 111 is formed. The method for manufacturing the semiconductor device layout structure further includes the following operation. A first protruding pattern 121 is formed at one end of the connection pattern in the first direction, and a second protruding pattern 122 is formed at another end of the connection pattern in the first direction, in which each of the widths E of the first protruding pattern 121 and the second protruding pattern 122 is equal to the width D2 of the second active area pattern 802, and each of the lengths F of the first protruding pattern 121 and the second protruding pattern 122 is less than or equal to the width E.

It is to be noted that in the embodiments of the disclosure, the first protruding pattern 121 may be formed first, and then second protruding pattern 122 is formed. In the embodiments of the disclosure, the forming sequence of the first protruding pattern 121 and the second protruding pattern 122 is not limited.

In some embodiments, a plurality of active area layout layers are arranged in an array in the first direction and the second direction. The method for manufacturing the semiconductor device layout structure further includes the following operation.

An isolation structure is formed between two active area layout layers arranged in the first direction.

In the embodiment of the disclosure, the isolation structure may be a shallow trench isolation structure or other insulating isolation structures.

The method for manufacturing the semiconductor device layout structure in the embodiment of the disclosure is similar to the semiconductor device layout structure in the abovementioned embodiments. The technical features not disclosed in detail in the embodiments of the disclosure may be understood with reference to the abovementioned embodiment.

With the method for manufacturing the semiconductor device layout structure provided by the embodiment of the disclosure, an active area layout layer including first active area patterns and second active area patterns each connected to at least two first active area patterns may be formed on a semiconductor substrate, a drain contact layer and a gate layer extending in the first direction may be formed on the first active area pattern, and a source contact layer may be formed on the second active area pattern, so that a new semiconductor device layout structure can be obtained, in which at least two semiconductor sub-devices share the same source contact layer. As such, it can not only improve the drive capability of the field effect transistor in the semiconductor device layout structure, but also reduce the problem of winding during connection with the back-end metal.

In the several embodiments provided in the disclosure, it should be understood that the disclosed device and method may be implemented in non-target manners. The described device embodiments are merely exemplary. For example, the unit division is merely logical function division and may be other division in an actual implementation. For example, a plurality of units or components may be combined or integrated into another system, or some features may be ignored or not performed. In addition, the displayed or discussed components may be coupled or directly coupled to each other.

The units described above as separate components may or may not be physically separated. Components presented as units may or may not be physical units, that is, may be located in one place or may be distributed over multiple network units. Part or all of these units may be selected according to practical requirements to achieve the objectives of the solutions of the embodiments.

The features disclosed in several method or device embodiments provided in the disclosure may be combined with each other without conflict, so as to obtain new method embodiments or device embodiments.

The above are only some embodiments of the embodiments of the disclosure, but the protection scope of the embodiments of the disclosure is not limited thereto. Any skilled in the art, within the technical scope disclosed by the embodiments of the disclosure, may easily think of variations or replacements, which should be covered within the protection scope of the embodiments of the disclosure. Therefore, the protection scope of the embodiments of the disclosure should be subject to the protection scope of the claims.

What is claimed is:

1. A semiconductor device layout structure, comprising:
an active area layout layer, wherein the active area layout layer comprises a plurality of first active area patterns, and at least one second active area pattern each connected to at least two of the plurality of first active area patterns;
a drain contact layer, wherein the drain contact layer is configured to form a plurality of drain contact plugs and is arranged on each first active area pattern;
a source contact layer, wherein the source contact layer is configured to form a source contact plug and is arranged on the at least one second active area pattern;
a gate layer, wherein the gate layer comprises a plurality of gate patterns extending in a first direction, and the plurality of gate patterns are arranged over the plurality of first active area patterns at a position away from the drain contact layer and are configured to form a plurality of gates,
wherein the gate layer, the active area layout layer, the source contact layer, and the drain contact layer are configured to form at least two semiconductor sub-devices, and the at least two semiconductor sub-devices share one source contact plug.

2. The semiconductor device layout structure according to claim 1, wherein the at least two semiconductor sub-devices formed by the layout structure are arranged parallel to each other in the first direction, and the at least two semiconductor sub-devices share one of the plurality of gates.

3. The semiconductor device layout structure according to claim 1, wherein the at least two semiconductor sub-devices formed by the layout structure are arranged parallel to each other in a second direction, and each semiconductor sub-device corresponds to a respective one of the plurality of gates arranged parallel to each other in the second direction, and wherein the first direction is perpendicular to the second direction.

4. The semiconductor device layout structure according to claim 2, wherein at least two semiconductor sub-devices formed by the layout structure are arranged parallel to each other in the first direction, at least two semiconductor sub-devices are arranged parallel to each other in a second direction, and at least four semiconductor sub-devices share one source contact plug, and wherein the first direction is perpendicular to the second direction.

5. The semiconductor device layout structure according to claim 2, wherein the active area layout layer further comprises at least one protruding pattern; and
wherein a width of the at least one protruding pattern is equal to a width of the at least one second active area pattern, and a length of the at least one protruding pattern is less than or equal to the width of the at least one protruding pattern, wherein the width of the at least one protruding pattern is a layout length of the at least one second active area pattern in a second direction.

6. The semiconductor device layout structure according to claim 4, wherein the active area layout layer further comprises at least one overlapping area pattern; and
wherein the at least four semiconductor sub-devices formed by the layout structure are arranged parallel to each other in the first direction, the layout structure comprises at least two second active area patterns connected to each other through the at least one overlapping area pattern.

7. The semiconductor device layout structure according to claim 6, wherein the active area layout layer further comprises at least two protruding patterns comprising a first protruding pattern and a second protruding pattern; and
wherein the first protruding pattern is connected to an end of a respective one of the at least two second active area patterns, and the second protruding pattern is connected to an end of another respective one of the at least two second active area patterns away from the first protruding pattern.

8. The semiconductor device layout structure according to claim 1, wherein the semiconductor device layout structure further comprises a wire layer, and the source contact layer, the drain contact layer and the gate layer are respectively connected to a source test node, a drain test node and a gate test node through the wire layer.

9. A method for manufacturing a semiconductor device layout structure, comprising:
providing a semiconductor substrate;
forming an active area layout layer on the semiconductor substrate, wherein the active area layout layer comprises a plurality of first active area patterns and a plurality of second active area patterns, and each second active area pattern is connected to at least two of the plurality of first active area patterns;
forming a drain contact layer on each first active area pattern, wherein the drain contact layer is configured to form a plurality of drain contact plugs;
forming a source contact layer on each second active area pattern, wherein the source contact layer is configured to form a source contact plug; and
forming a gate layer over the plurality of first active area patterns at a position away from the drain contact layer,
wherein the gate layer, the active area layout layer, the source contact layer and the drain contact layer are configured to form at least two semiconductor sub-devices, and the at least two semiconductor sub-devices share one source contact plug.

10. The method according to claim 9, further comprising:
forming a wire layer, wherein one end of the wire layer is respectively connected to the source contact layer, the drain contact layer and the gate layer, and the other end of the wire layer is respectively connected to a source test node, a drain test node and a gate test node.

11. The method according to claim 9, wherein forming the active area layout layer on the semiconductor substrate comprises:
forming the plurality of first active area patterns arranged in an array in a first direction and a second direction on the semiconductor substrate, wherein each first active area pattern extends in the second direction, and the first direction is perpendicular to the second direction;
forming the plurality of second active area patterns in the first direction, wherein the plurality of second active area patterns extend in the first direction and are spaced apart from each other, and wherein four first active area patterns of the plurality of first active area patterns are connected to a respective one of the plurality of second active area patterns; and
forming the active area layout layer through the plurality of first active area patterns and the plurality of second active area patterns.

12. The method according to claim 11, wherein forming the drain contact layer on each first active area pattern comprises:
forming the drain contact layer at an end of each first active area pattern away from the plurality of second active area patterns, wherein the drain contact layer is configured to form the plurality of drain contact plugs.

13. The method according to claim 11, wherein forming the source contact layer on each second active area pattern comprises:
forming the source contact layer at a central position of each second active area pattern, wherein the source contact layer is configured to form the source contact plug.

14. The method according to claim 11, wherein forming the gate layer over the plurality of first active area patterns at the position away from the drain contact layer comprises:
forming the gate layer comprising a plurality of gate patterns extending in the first direction over the plurality of first active area patterns, wherein the gate layer is arranged at the position away from the drain contact layer.

15. The method according to claim 11, further comprising:
forming an overlapping area pattern, which is connected to two adjacent second active area patterns of the plurality of second active area patterns, between the two adjacent second active area patterns in the first direction, wherein a width of the overlapping area pattern is equal to a width of each second active area pattern, and the width of the overlapping area pattern refers to a layout length of each second active area pattern in the second direction.

16. The method according to claim 15, wherein the two adjacent second active area patterns and the overlapping area pattern connected to the two adjacent second active area patterns form a connection pattern after forming the overlapping area pattern; and
wherein the method further comprises:
forming a first protruding pattern at one end of the connection pattern in the first direction, and forming a second protruding pattern at another end of the connection pattern in the first direction, wherein each of a width of the first protruding pattern and a width of the second protruding pattern is equal to the width of each second active area pattern, and each of a length of the first protruding pattern and a length of the second protruding pattern is less than or equal to the width of each second active area pattern.
